(19) United States
(12) Patent Application Publication
(10) Pub. No.: US 2025/0211200 A1
(43) Pub. Date: Jun. 26, 2025

(54) ELASTIC WAVE DEVICE, MANUFACTURING METHOD THEREOF, AND ELECTRONIC MODULE

(71) Applicant: QUANZHOU SANAN INTEGRATED CIRCUIT CO., LTD., QUANZHOU (CN)

(72) Inventors: Yenfu LIN, QUANZHOU (CN); Tianyi SUN, QUANZHOU (CN)

(73) Assignee: QUANZHOU SANAN INTEGRATED CIRCUIT CO., LTD., QUANZHOU (CN)

(21) Appl. No.: 18/885,746

(22) Filed: Sep. 16, 2024

(30) Foreign Application Priority Data
Dec. 20, 2023 (CN) 202311779209.8

(51) Int. Cl. H03H 9/17; H03H 3/02; H03H 9/13; H05K 1/18

(52) U.S. Cl. CPC H03H 9/17; H03H 3/02; H03H 9/13; H05K 1/181

(57) ABSTRACT

The present application provides an elastic wave device, a manufacturing method thereof, and an electronic module. The elastic wave device includes a supporting substrate, a piezoelectric layer, and a plurality of interdigital transducers electrodes. The piezoelectric layer is formed on the supporting substrate. A surface of the piezoelectric layer away from the supporting substrate has a damage layer, and a thickness of the damage layer is less than 0.00075λ. The multiple interdigital transducers electrodes are spaced apart from each other and arranged on a side of the piezoelectric layer away from the supporting substrate. A distance between two adjacent interdigital transducers electrodes is less than 3 μm. λ is a wavelength of an elastic wave of the elastic wave device, and is determined based on an electrode period of the plurality of interdigital transducers electrodes.

### CROSS REFERENCE TO RELATED APPLICATIONS

The present disclosure claims priority to Chinese Patent Application No. 202311779209.8 filed Dec. 20, 2023, the contents of which are herein incorporated by reference in its entirety.

### TECHNICAL FIELD

The present disclosure relates to the field of processing and manufacturing technologies for electronic devices, in particular to an elastic wave device, a manufacturing method thereof, and an electronic module.

### BACKGROUND

A filter structure includes an elastic wave device, a thickness of a piezoelectric layer in the elastic wave device determines a central frequency range of the filter. A high frequency filter has a thinner piezoelectric layer, such that a same error may cause more severe frequency shifts for the high frequency filter. Therefore, it is expected to obtain a piezoelectric layer with smaller thickness fluctuations to ensure that the central frequency of the filter is in a center of target.

In the related art, a thickness range of a piezoelectric layer of a composite base is controlled by an etching technology. However, the related etching technology may generate a thick damage layer on a surface of the piezoelectric layer, causing significant insertion loss in the filter, thereby reducing an electrical performance of the filter.

### SUMMARY

The present disclosure provides an elastic wave device including a supporting substrate, a piezoelectric layer, and multiple interdigital transducers electrodes. The piezoelectric layer is formed on the supporting substrate. A surface of the piezoelectric layer away from the supporting substrate has a damage layer, and a thickness of the damage layer is less than 0.00075λ. The multiple interdigital transducers electrodes are spaced apart from each other and arranged on a side of the piezoelectric layer away from the supporting substrate. A distance between two adjacent interdigital transducers electrodes of the multiple interdigital transducers electrodes is less than 3 μm. λ is a wavelength of an elastic wave of the elastic wave device, and is determined based on an electrode period of the multiple interdigital transducers electrodes.

The present disclosure provides a manufacturing method of an elastic wave device, including: providing a supporting substrate; forming a piezoelectric layer onto the supporting substrate; generating a damage layer on a surface of the piezoelectric layer away from the supporting substrate, and the thickness of the damage layer being less than 0.00075λ; forming multiple interdigital transducers electrodes spaced apart from each other on the piezoelectric layer, a distance between two adjacent interdigital transducers electrodes of the multiple interdigital transducers electrodes being less than 3 μm. A is a wavelength of an elastic wave of the elastic wave device, and is determined based on an electrode period of the plurality of interdigital transducers electrodes.

The present disclosure provides an electronic module including the elastic wave device mentioned above.

### BRIEF DESCRIPTION OF THE DRAWINGS

In order to make the technical solutions described in embodiments of the present disclosure more clearly, the drawings used for description of some embodiments are described. Apparently, the drawings in the following description only illustrate some embodiments of the present disclosure. For those skilled in the art, other drawings may be acquired according to the drawings without any creative work.

FIG. 1 is a structural schematic view of a first embodiment of a composite base according to the present disclosure.

FIG. 2 is a structural schematic view of a second embodiment of a composite base according to the present disclosure.

FIG. 3 is a structural schematic view of a third embodiment of a composite base according to the present disclosure.

FIG. 4 is a schematic flowchart of a manufacturing method of a composite base according to some embodiments of the present disclosure.

FIG. 5 is a diagram of characteristic comparison of filters.

FIG. 6 is a structural schematic view of a first embodiment of a filter according to the present disclosure.

FIG. 7 is a structural schematic view of a second embodiment of a filter according to the present disclosure.

### DETAILED DESCRIPTIONS

The technical solutions in embodiments of the present disclosure are clearly and completely described in conjunction with the drawings in the embodiments of the present disclosure. It may be understood that the embodiments are only used to explain but not used to limit the present disclosure. In addition, it should be noted that for ease of description, only some, but not all, of structures relevant to the present disclosure are shown in the drawings. All other embodiments acquired by those skilled in the art based on the embodiments in the present disclosure without the creative work are all within the scope of the present disclosure.

“Embodiment” mentioned in the present disclosure means that specific features, structures, or characteristics described in conjunction with embodiments may be included in at least one embodiment of the present disclosure. Some embodiments including the phrase appearing in various positions in the specification does not necessarily refer to the same embodiment, and does not independents or alternative embodiment that are mutually exclusive with other embodiments. Those skilled in the art explicitly and implicitly understand that the embodiments described in the present disclosure can be combined with other embodiments.

The terms “first”, “second”, and the like used in the present disclosure are used to distinguish different objects, and are not intended to describe a specific order. Furthermore, the terms “include” and “have”, and any modification thereof are intended to cover un-exclusive inclusion. For example, a process, method, system, product, or device that includes a series of operations or units is not limited to the listed operations or units, but optionally also includes operations or units not listed, or optionally includes other operations or units inherent to the process, method, product, or device.

Furthermore, although the terms “first”, “second”, and the like are used several times in the present disclosure to describe various data (various components, various applications, various instructions, or various operations) and the like, the various data (various components, various applications, various instructions, or various operations) should not be limited by the terms. The terms are only used to distinguish one data (component, application, instruction, or operation) from another data (component, application, instruction, or operation). For example, first position information may be referred to as second position information, and the second position information may be referred to as the first position information, simply because the scopes included in both of them are different, without departing from the scope of the present disclosure. Both the first position information and the second position information are collections of various position and pose information, but both of them are not the same collections of position and pose information.

In a filter structure, a thickness of a piezoelectric layer in the elastic wave device determines a central frequency range of the filter. A high frequency filter has a thinner piezoelectric layer, such that a same error may cause more severe frequency shifts. Therefore, it is expected to obtain a piezoelectric layer with smaller thickness fluctuations to ensure that the central frequency of the filter is in a center of target. In addition, in a manufacturing process of a composite base for filter, it may be manufactured through bonding, thinning, and polishing. However, due to unstable process and different topographies in different parts of a supporting substrate, thicknesses of different parts of a bonded piezoelectric layer may different, making it difficult to control an uniformity of the thickness of the piezoelectric layer, resulting in a poor frequency concentration of the filter manufactured based on the composite base, and then increasing the frequency range of the filter and reducing yield rate. In the related art, a thickness range of the piezoelectric layer of the composite base is controlled by an etching technology. However, the etching technology will generate a thick damage layer on a surface of the piezoelectric layer, causing significant insertion loss in the filter, thereby reducing an electrical performance of the filter.

Therefore, an elastic wave device, a manufacturing method thereof, and an electronic module based on the elastic wave device, such as a surface acoustic wave filter, are provided. The elastic wave device of the present disclosure may effectively reduce the thickness of the damage layer, reduce the insertion loss generated by the filter, thereby improving the frequency concentration of the filter and ensuring the electrical performance of a subsequent product.

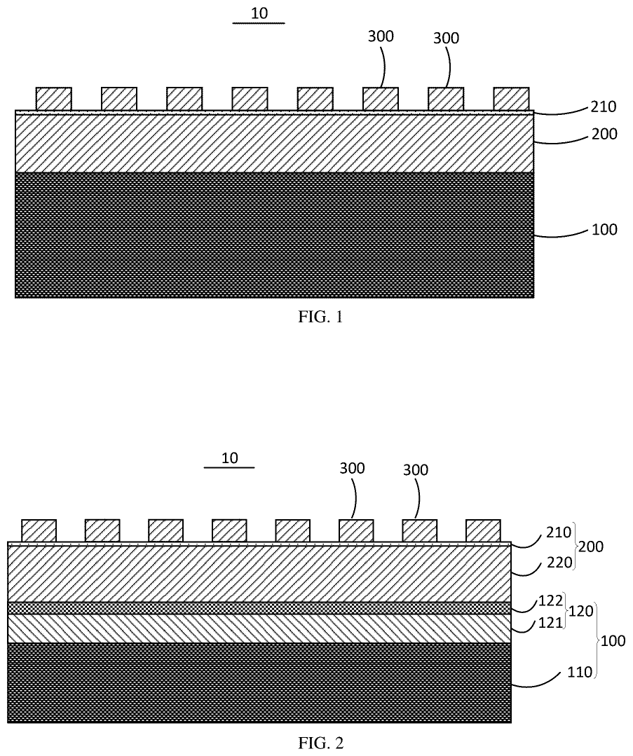

As shown in FIG. 1, FIG. 1 is a structural schematic view of a first embodiment of a composite base according to the present disclosure.

As shown in FIG. 1, an elastic wave device 10 includes a supporting substrate 100, a piezoelectric layer 200, and multiple interdigital transducers electrodes 300. The piezoelectric layer 200 is bonded to or formed on the supporting substrate 100. A surface of the piezoelectric layer 200 away from the supporting substrate 100 has a damage layer 210, and a thickness of the damage layer 210 is less than 0.00075λ. The multiple interdigital transducers electrodes 300 are spaced apart from each other and arranged on a side of the piezoelectric layer 200 away from the supporting substrate 100. A distance between two adjacent interdigital transducers electrodes 300 is less than 3 μm. A is a wavelength of an elastic wave of the elastic wave device 10, and is determined based on an electrode period of the multiple interdigital transducers electrodes 300.

The supporting substrate 100 is a bottom plate that supports the entire device, and the piezoelectric layer is a crystal material that generates voltage between the two end faces when subjected to pressure.

The supporting substrate 100 has a first surface, and the piezoelectric layer 200 has a second and a third surfaces opposite to each other. For example, a bottom surface of the piezoelectric layer 200 is the second surface, and a top surface of the piezoelectric layer 200 is the third surface. The first surface of the supporting substrate 100 is served as a bonding surface of the supporting substrate 100, and the second surface of the piezoelectric layer 200 is served as the bonding surface of the piezoelectric layer 200, such that the supporting substrate 100 is bonded to or formed on the second surface of the piezoelectric layer 200 through the first surface. In addition, the surface of the piezoelectric layer 200 away from the supporting substrate 100 has a damage layer 210, and a thickness of the damage layer 210 is less than 0.00075λ. Multiple interdigital transducers electrodes 300 are spaced apart from each other and arranged on a side of the piezoelectric layer 200 away from the supporting substrate 100, and a distance between two adjacent interdigital transducers electrodes 300 is less than 3 μm, λ is a wavelength of an elastic wave of the elastic wave device 10, and is determined based on the electrode period of the interdigital transducers electrodes 300.

The elastic wave is a type of stress wave, which is a propagation form of a stress and a strain perturbation, that is, a form of a stress and a strain caused by a perturbation or an external force transmitted in the elastic wave device 10. There is elastic force that interacts with each other between particles in the elastic wave device 10. After a particle leaves an equilibrium position due to the perturbation or the external force, an elastic restoring force causes the particle to vibrate, resulting in displacement and vibration of surrounding particles. As a result, the vibration propagates in the elastic media, accompanied by energy transmission. The stress and strain will change wherever the vibration goes.

In this embodiment, in order to reduce the insertion loss generated by a subsequent filter, the thickness of the loss layer on the piezoelectric layer is arranged to be less than 0.00075λ, and thickness uniformity of the piezoelectric layer 200 is ensured, so as to achieve good frequency concentration required for the filter manufactured based on the composite base.

As shown in FIG. 2, FIG. 2 is a structural schematic view of a second embodiment of a composite base according to the present disclosure.

As shown in FIG. 2, the elastic wave device 10 includes the supporting substrate 100, the piezoelectric layer 200, and the multiple interdigital transducers electrodes 300. The piezoelectric layer 200 is bonded to or formed on the supporting substrate 100. The surface of the piezoelectric layer 200 away from the supporting substrate 100 has the damage layer 210, and the thickness of the damage layer 210 is less than 0.00075λ. The multiple interdigital transducers electrodes 300 are spaced apart from each other and arranged on the side of the piezoelectric layer 200 away from the supporting substrate 100. The distance between two adjacent interdigital transducers electrodes 300 is less than 3 μm, λ is a wavelength of an elastic wave of the elastic wave device 10, and is determined based on the electrode period of the interdigital transducers electrodes 300.

The electrode period of the interdigital transducers electrodes 300 is determined based on four structural parameters of the interdigital transducers electrode structure, and includes the number of pairs of electrode pairs, a width of each interdigital transducers electrode, an interdigital pitch or a distance between two adjacent interdigital transducers electrodes, and a thickness of each interdigital transducers electrode. By analyzing a calculation formula for a resistance value of one interdigital transducers electrode, it may be found that the greater the ratio of the with to length of the interdigital transducers electrode, the greater the density of the interdigital transducers electrode, the lower an initial resistance of the interdigital transducers electrode, the greater the sensitivity and response speed of a sensor. When the size of the interdigital transducers electrode structure is reduced to be less than a micrometer level, a weak change of the resistance in the interdigital transducers electrode structure may be sensitively detected, such that the sensitivity of the interdigital transducers electrode sensor may be significantly improved. An electric field distribution around the interdigital transducers electrode structure may be obtained through theoretical analysis and numerical simulation calculations. The calculation results show that the electric field strength of the interdigital transducers electrode sensor is approximately inversely proportional to the electrode thickness, and the thicker the electrodes, the smaller the electric field strength. In addition, the number of pairs of electrode pairs has little effect on a signal-to-noise ratio of the interdigital transducers electrode sensor. Reducing the distance between interdigital transducers electrodes may increase the signal-to-noise ratio and an amplitude of a signal, effectively increase speed of chemical reactions, and accelerate establishment of reaction processes, thereby improving a performance of the sensor and shortening a reaction duration of the interdigital transducers electrode sensor. The reduction of the width of the electrodes of the interdigital transducers electrode sensor may increase the signal-to-noise ratio and reduce the amplitude of the detection signal.

In some embodiments, the supporting substrate 100 may include a substrate 110 and at least one supporting layer 120, and the bonding surface of the supporting substrate 100 may be a horizontal surface or a curved surface. The bonding surface of the piezoelectric layer 200 and the bonding surface of the supporting substrate 100 may be arranged face to face, such that the supporting substrate 100 and the piezoelectric layer 200 are bonded through corresponding bonding surfaces.

Two layers of supporting layers and the bonding surface of the supporting substrate 100 being horizontal surfaces are taken as an example. The supporting layer 120 includes a first supporting layer 121 and a second supporting layer 122. The first supporting layer 121 is close to the substrate 110, and the second supporting layer 122 is further from the substrate 110 than the first supporting layer 121. The first supporting layer 121 covers the substrate 110, that is, the first supporting layer 121 is located between the substrate 110 and the piezoelectric layer 200. The second supporting layer 122 covers the first supporting layer 121, that is, the second supporting layer 122 is located between the first supporting layer 121 and the piezoelectric layer 200, and the piezoelectric layer 200 is bonded to or formed on the second supporting layer 122. The piezoelectric layer 200 may include a piezoelectric part 220 and a damage layer 210, that is, the piezoelectric part 220 is bonded to or formed on the second supporting layer 122, and the damage layer 210 covers the piezoelectric part 220. A thickness of the first supporting layer 121 is greater than that of the damage layer 210, and a thickness of the second supporting layer 122 is greater than that of the damage layer 210.

The substrate 110 may be any suitable material known in the related art, such as at least one of the following materials: silicon (Si), germanium (Ge), germanium silicon (SiGe), silicon carbide (SiC), carbon germanium silicon (SiGeC), indium arsenide (InAs), gallium arsenide (GaAs), indium phosphide (InP), and other compound semiconductors in group III/V, etc. The substrate 110 may include a multilayer structure including these semiconductors, or silicon on insulator (SOI), strained silicon on insulator (SSOI), strained silicon germanium on insulator (S—SiGeOI), silicon germanium on insulator (SiGeOI), germanium on insulator (GeOI), high resistance silicon, sapphire, spinel, or polycrystalline materials, etc.

The first supporting layer 121 may be at least one or a combination of two or more of the following materials: silicon oxide, silicon nitride, and aluminum oxide, etc. The thickness of the first supporting layer 121 is less than 2λ, λ is a wavelength. For example, when λ is 4 μm (4000 nm), 0.00025λ may be 1 nm, that is, the thickness of the first supporting layer 121 is less than 8000 nm. For example, the thickness of the first supporting layer 121 may be 6000 nm, 6400 nm, or 7000 nm.

The second supporting layer 122 may be at least one of the following materials: titanium, tungsten, and silicon, etc. For example, when λ is 4 μm (4000 nm), the thickness of the second supporting layer 122 is less than 0.004λ, that is, the thickness of the second supporting layer 122 is less than 16 nm, for example, the thickness of the second supporting layer 122 is 10 nm, 12 nm, or 14 nm.

The piezoelectric layer 200 may be a piezoelectric single crystal or a piezoelectric polycrystalline, and may be at least one of the following materials: barium titanate (BT), lead zirconate titanate (PZT), modified PZT, lead niobate, lead barium lithium niobate (PBLN), modified lead titanate (PT), crystal (quartz crystal), lithium gallate, lithium germanate, titanium germanate, iron transistor lithium niobate, and lithium tantalate, etc. The thickness of piezoelectric layer 200 is less than 1λ, that is, the thickness of piezoelectric layer 200 is less than 4000 nm, for example, the thickness of piezoelectric layer is 500 nm, 1000 nm, or 2000 nm. The thickness of the damage layer 210 is less than 0.00075λ, that is, the thickness of the damage layer 210 is less than 3 nm, for example, the thickness of the damage layer 210 is 1 nm, 0.8 nm, or 0.5 nm.

In some embodiments, the piezoelectric layer 200 is configured as follows. The difference between the maximum and minimum of the thickness of the piezoelectric substrate 200 is less than 40 nm, such that the thickness uniformity of the piezoelectric layer 200 may be ensured regardless of the topography of the supporting substrate 100.

In this embodiments, even if the supporting substrate 100 has different topographies in different parts, the difference between the maximum and minimum of the thickness of the piezoelectric layer 200 may be controlled to be less than 40 nm, ensuring the thickness uniformity of the piezoelectric layer 200 and achieving good frequency concentration required for the filter manufactured based on the composite base. In addition, the damage layer 210 on the side of the piezoelectric layer 200 away from the supporting substrate 100 is controlled to be less than 3 nm, which not only improves frequency concentration but also reduces abnormal insertion loss caused by the damage layer, thereby improving the electrical performance of the subsequent device.

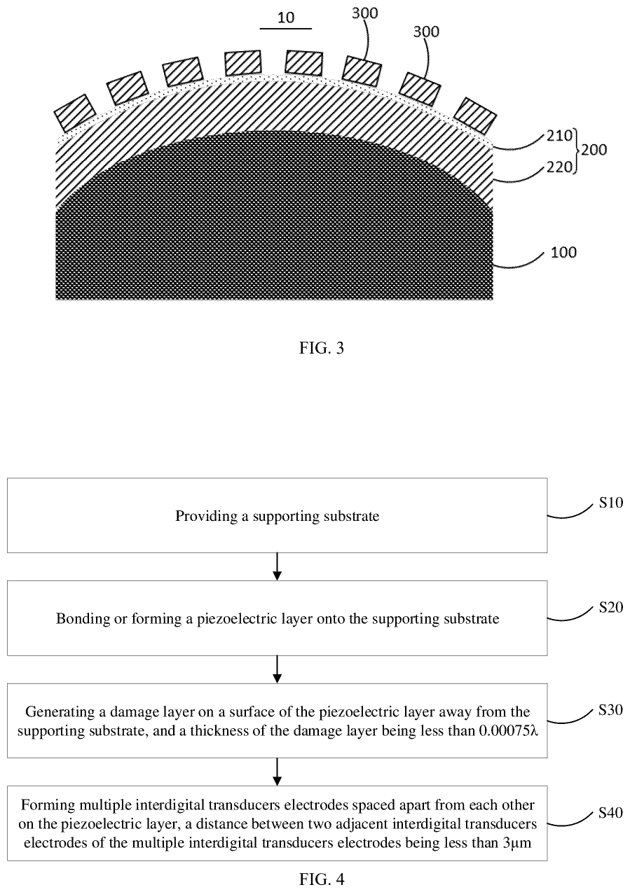

As shown in FIG. 3, FIG. 3 is a structural schematic view of a third embodiment of a composite base according to the present disclosure.

As shown in FIG. 3, the composite base 10 includes the supporting substrate 100, the piezoelectric layer 200, and the multiple interdigital transducers electrodes 300. The piezoelectric layer 200 is bonded to or formed on the supporting substrate 100, and the difference between the maximum and minimum of the thickness of the piezoelectric layer is less than 40 nm. The surface of the piezoelectric layer 200 away from the supporting substrate 100 has a damage layer 210, that is, the damage layer 210 is located on the side of the piezoelectric layer 200 away from the supporting substrate 100, and the thickness of the damage layer 210 is less than 0.00075λ. The piezoelectric layer 200 includes the piezoelectric part 220 and the damage layer 210.

The thickness of the damage layer 210 is less than 3 nm, such as 1 nm, 0.8 nm, or 0.5 nm.

The bonding surface of the supporting substrate 100 may be an uneven and imperfect horizontal surface, such as a curved surface or an arc surface, etc. The bonded supporting substrate 100 is tightly connected to or attached to the piezoelectric layer 200. Therefore, the bonding surface of the piezoelectric layer 200 may be an arc surface. For example, the bonding surface of the supporting substrate 100 is an outer arc surface, and the bonding surface of the piezoelectric layer is an inner arc surface.

Because the difference between the maximum and minimum of the thickness of the piezoelectric layer 200 is less than 40 nm, the surface of the piezoelectric layer 200 away from the supporting substrate 100 is an outer arc surface. For example, the bonding surface of piezoelectric layer 200 is parallel to the outer arc surface away from supporting substrate 100.

Correspondingly, the damage layer 210 generated through etching the piezoelectric layer 200 with an ion beam is arc-shaped, covers the surface of the piezoelectric layer 200.

Because the bonding surface of the supporting substrate 100 is curved, the traditional thinning and polishing process cannot achieve the thickness uniformity of the piezoelectric layer 200. That is, the difference between the maximum and minimum of the thickness of the piezoelectric layer 200 in the thinning and polishing process alone is great, reaching 0.4 μm, which reduces the frequency concentration of the filter. In this embodiment, the ion beam is configured to etch the piezoelectric layer 200, which may effectively reduce the difference between the maximum and minimum of the thickness of the piezoelectric layer 200 to be less than 40 nm, and the thickness of the damage layer 210 is less than 3 nm, reducing abnormal insertion loss caused by the damage layer, improving the frequency concentration of the filter, and ensuring the electrical performance of the filter.

Some embodiments of the present disclosure include a method for manufacturing a composite base as follows.

As shown in FIG. 4, FIG. 4 is a schematic flowchart of a manufacturing method of a composite base according to some embodiments of the present disclosure.

As shown in FIG. 4, the method may include the following operations.

Operation S10 includes providing a supporting substrate.

The supporting substrate 100 may include a substrate 110 and at least one supporting layer 120, and a bonding surface of the supporting substrate 100 may be a horizontal surface or a curved surface. A bonding surface of the piezoelectric layer 200 and a bonding surface of the supporting substrate 100 are arranged face to face, such that the supporting substrate 100 and the piezoelectric layer 200 are bonded to each other through corresponding bonding surfaces.

Two layers of supporting layers and the bonding surface of the supporting substrate 100 being horizontal surfaces are taken as an example. The supporting layer 120 includes a first supporting layer 121 and a second supporting layer 122. The first supporting layer 121 is close to the substrate 110, and the second supporting layer 122 is further from the substrate 110 than the first supporting layer 121. The first supporting layer 121 covers the substrate 110, that is, the first supporting layer 121 is located between the substrate 110 and the piezoelectric layer 200. The second supporting layer 122 covers the first supporting layer 121, that is, the second supporting layer 122 is located between the first supporting layer 121 and the piezoelectric layer 200, and the piezoelectric layer 200 is bonded to or formed on the second supporting layer 122. The piezoelectric layer 200 may include a piezoelectric part 220 and a damage layer 210, that is, the piezoelectric part 220 is bonded to or formed on the second supporting layer 122, and the damage layer 210 covers the piezoelectric part 220. A thickness of the first supporting layer 121 is greater than that of the damage layer 210, and a thickness of the second supporting layer 122 is greater than that of the damage layer 210.

Operation S20 includes bonding or forming a piezoelectric layer onto the supporting substrate.

The piezoelectric layer 200 may be a piezoelectric single crystal or a piezoelectric polycrystalline, and may be at least one of the following materials: barium titanate (BT), lead zirconate titanate (PZT), modified PZT, lead niobate, lead barium lithium niobate (PBLN), modified lead titanate (PT), crystal (quartz crystal), lithium gallate, lithium germanate, titanium germanate, and iron transistor lithium niobate, lithium tantalate, and lithium niobate, etc. In some embodiments, the thinner the thickness of the piezoelectric layer 200, the more effective in increasing a Q value. For example, the piezoelectric layer 200 is one of piezoelectric material which can be LiTaO3 with Y cut angle at 15-52° and wave propagation along X direction. Q is a quality factor of a filter, and reflects a selectivity of a filter to a frequency. A large Q value indicates a narrow passband width, a good sensitivity of the filter, a good selectivity to the frequency band, and a good filtering effect.

The bonding surface of the piezoelectric layer 200 is bonded to or formed on the corresponding bonding surface of the supporting substrate 100, that is, the piezoelectric layer 200 is bonded to or formed on the second supporting layer 122 of the supporting substrate 100, such that the piezoelectric layer 200 and the supporting substrate 100 form a one-piece structure.

In some embodiments, when the morphology of the supporting substrate 100 is not flat, the thickness of the bonded piezoelectric layer 200 will change accordingly, that is, the thickness of different parts of the piezoelectric layer 200 is different, and there may be some parts of the piezoelectric layer 200 with greater thickness. Therefore, in order to reduce the difficulty of ion beam etching, the piezoelectric layer 200 may be thinned and polished first. For example, when the total thickness of the bonded piezoelectric layer 200 and the supporting substrate 100 exceeds a threshold thickness, the piezoelectric layer 200 may be thinned and polished such that the total thickness of the piezoelectric layer 200 and the supporting substrate 100 is less than or equal to the threshold thickness.

The threshold thickness may be set based on a design requirement, and is not limited here. The thinning and polishing include grinding the side of the piezoelectric layer 200 in the composite base 10 away from the supporting substrate 100 through a grinding wheel processing machine and then a grinding machine. Further thinning and polishing may be achieved through chemical mechanical grinding, for example, reducing the thickness of the piezoelectric layer 200 through mirror polishing using a chemical mechanical polishing (CMP) grinding machine.

Operation S30 includes etching the piezoelectric layer through an ion beam to form a composite base, and generating a damage layer on the surface of the piezoelectric layer away from the supporting substrate, and the thickness of the damage layer being less than 0.00075λ.

In some embodiments, the difference between the maximum and minimum of the thickness of the etched piezoelectric layer is less than 40 nm.

In order to etch the piezoelectric layer 200, the ion beam etching method may be used to etch the piezoelectric layer 200 to trim the piezoelectric layer 200.

After the supporting substrate 100 and the piezoelectric layer 200 is bonded, thinned and polished, the side of the piezoelectric layer 200 away from the supporting substrate 100 is etched through the ion beam to form a corresponding composite base. The difference between the maximum and minimum of the thickness of the etched piezoelectric layer 200 is less than 40 nm.

In some embodiments, before the ion beam etching, it is necessary to determine etching process parameters of the ion beam, such as emission current and emission voltage, such that the thickness of the etched piezoelectric layer 200 meets a corresponding device requirement.

The etching process parameters may be determined based on a thickness requirement of the piezoelectric layer 200, that is, each part of the bonded piezoelectric layer has a corresponding initial thickness, and is required to reach a target thickness after etched, which is the thickness requirement of the piezoelectric layer 200. Therefore, a certain thickness of the piezoelectric layer 200 is required to be etched away. The thickness that is required to be etched away is defined as a sacrificial thickness. Therefore, it is required to etch away the sacrificial thickness through the ion beam and set corresponding etching process parameters.

When the piezoelectric layer 200 is etched though the ion beam, the damage layer 210 is generated on the etched surface of the piezoelectric layer 200. When the thickness of the damage layer 210 is great, it will cause significant insertion loss. For example, when the thickness of the damage layer 210 is greater than 3 nm, such as 3-10 nm, the generated insertion loss is 1.47 dB, resulting in a corresponding electromechanical coupling coefficient of 7.8% for the filter. Moreover, when the distance between adjacent interdigital transducers electrodes is less than 3 μm, the impact of the damage layer 210 on insertion loss is significantly increased. Therefore, in some embodiment of the present disclosure, in a case where the distance between adjacent interdigital transducers electrodes is less than 3 μm, especially 1 μm. On the one hand, the ion beam etching method is used to etch the piezoelectric layer 200 to improve its thickness uniformity. On the other hand, after the ion beam etching, the surface of the piezoelectric layer is polished to ensure that the thickness of the damage layer 210 of the piezoelectric layer 200 is less than a sensitive thickness of the damage layer 210 corresponding to the filter, thereby ensuring the characteristics of the filter. It should be understood that, when the thickness of the damage layer 210 reaches the sensitive thickness, the performance of the filter is reduced significantly.

Therefore, in some embodiments of the present disclosure, in order to reduce the thickness of the damage layer 210, a current range of the emission current is set to 10 mA-15 mA, such as 12 mA, 13 mA, or 14 mA. A voltage range of the emission voltage is set to 800V-1200V, such as 900V, 1000V, or 1100V. In this way, the ion beam corresponding to the set emission current and emission voltage is emitted, and the etched surface of the piezoelectric layer is etched by the ion beam. The thickness of the damage layer 210 generated by etching is less than 3 nm, such as 2 nm, 1 nm, 0.8 nm or 0.7 nm. When the thickness of the damage layer is less than 1 nm, the insertion loss of the corresponding filter is 1.113 dB, and the electromechanical coupling coefficient is 8.31%.

Due to the use of the ion beam to etch the piezoelectric layer 200, a surface roughness of the etched piezoelectric layer 200 is reduced. For example, the surface roughness of the piezoelectric layer 200 in some embodiments of the present disclosure is measured to be 0.178 nm. The surface roughness refers to a smoothness of the piezoelectric layer 200. The smoother the surface of the piezoelectric layer 200, the better the electrical performance of the corresponding device.

In some embodiments, the thickness of the supporting substrate 100 may be used as a reference to 200, and the total initial thickness may be obtained after the piezoelectric layer is bonded. The sacrificial thickness to be etched away may be determined based on the thickness of the supporting substrate 100, the initial thickness, and the target thickness.

In order to obtain thickness distribution data of the piezoelectric layer 200, an optical film thickness measuring device with laser interference may be configured to measure the thickness of the ground piezoelectric layer 200 to obtain the thickness distribution data of the piezoelectric layer 200.

For example, a coordinate system is established, and the thickness of the supporting substrate 100 on each horizontal axis, the total initial thickness after the piezoelectric layer 200 is bonded, and the target thickness on each horizontal axis are obtained; each sacrificial thickness required to be etched away on each horizontal axis is determined. In addition, a coordinate distance, i.e., a distance between a position to be etched and the ion beam, may be based on a diameter of the ion beam spot, and thickness may be measured through optical film thickness device.

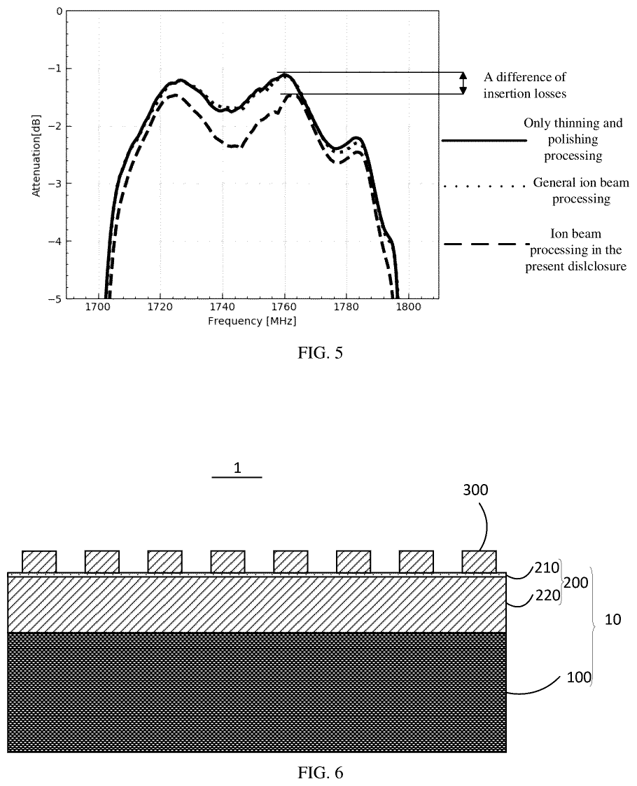

As shown in FIG. 5, FIG. 5 is a diagram of characteristic comparison of filters.

FIG. 5 was measured on the basis of the supporting substrate being a horizontal plate. The short broken line represents characteristics of a filter that is not etched through an ion beam, and the insertion loss is 1.148 dB. The solid line represents characteristics of a filter that is etched through a general ion beam, and the insertion loss is 1.47 dB. The long broken line represents characteristics of a filter that is etched through the optimized ion beam in some embodiments of the present disclosure, and the insertion loss is 1.113 dB.

It can be seen that using the ion beam to etch the piezoelectric layer 200 may effectively control the thickness uniformity, that is, the difference between the maximum and minimum of the thickness of the piezoelectric layer 200 is less than 60 nm. However, the thickness of the damage layer 210 generated by etching is great, ranging from 3-10 nm, which will cause significant insertion loss and reduce the performance of the filter. When the optimized ion beam in some embodiments of the present disclosure is configured to etch the piezoelectric layer 200, the thickness uniformity of the piezoelectric layer 200 may be effectively controlled, and a thin damage layer 210 may be generated which is less than 3 nm. In some embodiments, the thickness of the damage layer 210 is less than 1 nm, resulting in a little insertion loss and ensuring good frequency concentration of the filter.

Operation S40 includes forming multiple interdigital transducers electrodes spaced apart from each other on the piezoelectric layer; a distance between two adjacent interdigital transducers electrodes of the multiple interdigital transducers electrodes is less than 3 μm.

The structure parameters of the interdigital transducers electrodes include: the number of pairs of the electrode pairs, a width of each interdigital transducers electrode, an interdigital pitch or a distance between two adjacent interdigital transducers electrodes, and a thickness of each interdigital transducers electrode. The four structure parameters of the interdigital transducers electrodes affect the electrical performance of the subsequent product.

The number of pairs of interdigital transducers electrode pairs, the width of each interdigital transducers electrode, and the thickness of each interdigital transducers electrode may be designed based on actual needs, which are not limited here. The interdigital pitch or the distance between two adjacent interdigital transducers electrodes is configured to be less than 3 μm, so as to match the aforementioned configuration that the thickness of the damage layer of the piezoelectric layer 200 is configured to be less than 0.00075λ, ensuring the thickness uniformity of the piezoelectric layer 200, thereby achieving the good frequency concentration required for the filter manufactured based on the composite base.

In some embodiments, the distance between two adjacent interdigital transducers electrodes may be configured to be less than 1 μm to match the aforementioned configuration that the thickness of the damage layer of the piezoelectric layer 200 is configured to be less than 0.00075λ, further ensuring the thickness uniformity of the piezoelectric layer 200, thereby achieving the good frequency concentration required for the filter manufactured based on the composite base.

In this embodiment, the corresponding ion beam is emitted through optimized emission parameters, and then the piezoelectric layer 200 is etched to make the surface of the piezoelectric layer 200 smooth. The thickness of the piezoelectric layer 200 has good uniformity, which improves the frequency concentration of the filter, greatly reduces the thickness of the damage layer generated by the ion beam, reduces the insertion loss, and even avoids the occurrence of abnormal insertion loss, thereby effectively ensuring the electrical performance of the filter.

In addition, some embodiments of the present disclosure include a filter as follows.

As shown in FIG. 6, FIG. 6 is a structural schematic view of a first embodiment of a filter according to the present disclosure.

As shown in FIG. 6, the filter 1 includes the aforementioned elastic wave device 10, and the elastic wave device 10 may be manufactured through the manufacturing method of the aforementioned elastic wave device, or the elastic wave device 10 may be the aforementioned elastic wave device 10. That is, the elastic wave device 10 includes the supporting substrate 100 and the piezoelectric layer 200 that are bonded to each other. The multiple interdigital transducers electrodes 300 are spaced apart from each other and arranged on the side of the composite base away from the supporting substrate 100, that is, the interdigital transducers electrodes 300 are spaced apart from each other and arranged on the side of the piezoelectric layer 200 away from the supporting substrate 100.

The wavelength of the elastic wave of the elastic wave device is 2, and the distance between two adjacent interdigital transducers electrodes in the elastic wave device is an interdigitated transducer (IDT) distance, which may be designed based on a product type.

The supporting substrate served as a flat plate is taken as an example, the filter 1 includes the elastic wave device 10, and the elastic wave device 10 includes the supporting substrate 100, the piezoelectric layer 200, and the multiple interdigital transducers electrodes 300. The supporting substrate 100 is bonded to or formed on the piezoelectric layer 200, and the bonded piezoelectric layer 200 is etched through the ion beam to form the composite base. The thickness of the etched piezoelectric layer 200 is less than 3 μm, and the difference between the maximum and minimum of the thickness of the piezoelectric layer 200 is less than 40 nm. The etched surface of the etched piezoelectric layer 200 generates the damage layer 210 with a thickness of less than 3 nm, such as 1 nm. The thickness of damage layer that is less than or equal to 1 nm does not reach the sensitive thickness of the damage layer corresponding to the filter, therefore, the damage layer does not affect the characteristics of the filter. The interdigital transducers electrodes 300 spaced apart from each other are arranged on the damage layer 210, such that the above components form the filter.

In some embodiments, the distance between two adjacent interdigital transducers electrodes 300 is less than 3 μm, such as 2 μm, 1 μm, 0.8 μm, 0.5 μm, 0.4 μm, or 0.2 μm, etc.

In this embodiment, the filter is manufactured based on the composite base described above, thereby effectively improving the frequency concentration, reducing insertion loss, even avoiding abnormal insertion loss, and ensuring the electrical performance.

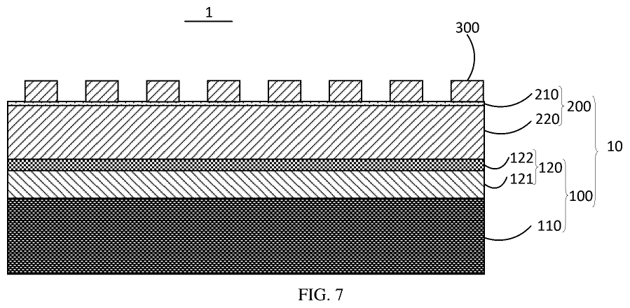

As shown in FIG. 7, FIG. 7 is a structural schematic view of a second embodiment of a filter according to the present disclosure.

As shown in FIG. 7, the filter 1 includes the composite base 10 and the multiple interdigital transducers electrodes 300. The composite base 10 includes the supporting substrate 100 and the piezoelectric layer 200 that are bonded to each other. The supporting substrate 100 includes the substrate 110 and the at least one supporting layer 120. For example, the at least one supporting layer 120 includes the first supporting layer 121 and the second supporting layer 122, and the damage layer 210 is generated on the surface of the piezoelectric layer 200 etched through the ion beam. The thickness of the damage layer 210 is less than 3 nm, such as 1 nm. The difference between the maximum and minimum of the thickness of the piezoelectric layer 200 is less than 40 nm.

Some embodiments of the present disclosure provide an electronic module including the at least one elastic wave device. For example, the module includes a wiring base, an integrated circuit (IC) component, the elastic wave device, an inductor, and a sealing part. For example, the IC component is arranged inside the wiring base. The IC component includes a switch circuit and a low-noise amplifier. The at least one elastic wave device is arranged on a main surface of the wiring base. The inductor is arranged on the main surface of the wiring base. The Inductor is configured for impedance matching. For example, the inductor is an integrated passive device (IPD). The sealing part seals the multiple electronic components, including elastic wave device.

In some embodiments of the present disclosure, it should be understood that the disclosed system and device may be implemented in other ways. For example, the system embodiments described above are merely illustrative. For example, the division of the above module of unit is only a logical function division. In actual implementation, there may be another division way. For example, multiple units or components may be combined or integrated into another system, or some features can be ignored or not executed.

The above are only some embodiments of the present disclosure, but are not to limit the scope of the present disclosure. The equivalent structures or equivalent process transformations made by using the description and the drawings of the present disclosure, or directly or indirectly applying the description and the drawings of the present disclosure to other relevant technical fields, are included in the scope of the present disclosure.

What is claimed is:

1. An elastic wave device, comprising:
a supporting substrate;
a piezoelectric layer, formed on the supporting substrate, wherein a surface of the piezoelectric layer away from the supporting substrate has a damage layer, and a thickness of the damage layer is less than 0.00075λ; and
a plurality of interdigital transducers electrodes, spaced apart from each other and formed on a side of the piezoelectric layer away from the supporting substrate, wherein a distance between two adjacent interdigital transducers electrodes of the plurality of interdigital transducers electrodes is less than 3 μm;
wherein λ is a wavelength of an elastic wave of the elastic wave device, and is determined based on an electrode period of the plurality of interdigital transducers electrodes.

2. The elastic wave device as claimed in claim 1, wherein the supporting substrate comprises:
a substrate; and
at least one supporting layer, arranged between the substrate and the piezoelectric layer; wherein one of the at least one supporting layer farthest from the substrate is formed on the piezoelectric layer, and has a thickness greater than the thickness of the damage layer.

3. The elastic wave device as claimed in claim 2, wherein the at least one supporting layer comprises:
a first supporting layer, located between the substrate and the piezoelectric layer; and
a second supporting layer, located between the first supporting layer and the piezoelectric layer; wherein a thickness of the first supporting layer and a thickness of the second supporting layer are respectively greater than the thickness of the damage layer.

4. The elastic wave device as claimed in claim 3, wherein the thickness of the first supporting layer is less than 2λ.

5. The elastic wave device as claimed in claim 3, wherein the thickness of the second supporting layer is less than 0.0042.

6. The elastic wave device as claimed in claim 1, wherein the thickness of the damage layer is less than 3 nm.

7. The elastic wave device as claimed in claim 1, wherein the thickness of the damage layer is less than or equal to 1 nm.

8. The elastic wave device as claimed in claim 1, wherein a difference between a maximum and a minimum of the thickness of the piezoelectric layer is less than 40 nm.

9. The elastic wave device as claimed in claim 1, wherein the distance between two adjacent interdigital transducers electrodes of the plurality of interdigital transducers electrodes is less than 1 μm.

10. The elastic wave device as claimed in claim 1, wherein an insertion loss of the elastic wave device is less than 1.4 dB.

11. A manufacturing method of an elastic wave device, comprising:
providing a supporting substrate;
forming a piezoelectric layer onto the supporting substrate;
generating a damage layer on a surface of the piezoelectric layer away from the supporting substrate, a thickness of the damage layer being less than 0.00075λ; and
forming a plurality of interdigital transducers electrodes spaced apart from each other on the piezoelectric layer; wherein a distance between two adjacent interdigital transducers electrodes of the plurality of interdigital transducers electrodes is less than 3 μm;
wherein λ is a wavelength of an elastic wave of the elastic wave device, and is determined based on an electrode period of the plurality of interdigital transducers electrodes.

12. The method as claimed in claim 11, wherein the generating a damage layer on a surface of the piezoelectric layer away from the supporting substrate, comprises:
etching the piezoelectric base through an ion beam to form a composite base, and generating the damage layer on a surface of the piezoelectric layer away from the supporting substrate.

13. The method as claimed in claim 12, wherein the etching the piezoelectric base through an ion beam to form a composite base, comprises:
determining etching process parameters of the ion beam based on a thickness requirement of the piezoelectric layer; wherein the etching process parameters comprise an emission current and an emission voltage, a current range of the emission current is 10 mA-15 mA, and a voltage range of the emission voltage is 800V-1200V; and
etching the piezoelectric layer, through the ion beam, based on the etching process parameters to form the composite base.

14. The method as claimed in claim 13, wherein,
the piezoelectric layer is etched based on the etching process parameters to control a thickness of the damage layer to be less than 1 nm.

15. An electronic module, comprising:
an elastic wave device, comprising:
a supporting substrate;
a piezoelectric layer, formed on the supporting substrate, wherein a surface of the piezoelectric layer away from the supporting substrate has a damage layer, and a thickness of the damage layer is less than 0.00075λ; and
a plurality of interdigital transducers electrodes, spaced apart from each other and arranged on a side of the piezoelectric layer away from the supporting substrate, wherein a distance between two adjacent interdigital transducers electrodes of the plurality of interdigital transducers electrodes is less than 3 μm;
wherein λ is a wavelength of an elastic wave of the elastic wave device, and is determined based on an electrode period of the plurality of interdigital transducers electrodes.

16. The electronic module as claimed in claim 15, comprising:
a wiring base, wherein the elastic wave device is arranged on a main surface of the wiring base;
an integrated circuit (IC) component, arranged in the wiring base, and comprising a switch circuit and a low-noise amplifier;
an inductor, arranged on the main surface of the wiring base, and configured for impedance matching; and
a sealing part, configured to seal the elastic wave device.

17. The electronic module as claimed in claim 15, wherein the supporting substrate comprises:
a substrate; and
at least one supporting layer, arranged between the substrate and the piezoelectric layer; wherein one of the at least one supporting layer farthest from the substrate is formed on the piezoelectric layer, and has a thickness greater than the thickness of the damage layer.

18. The electronic module as claimed in claim 17, wherein the at least one supporting layer comprises:
a first supporting layer, located between the substrate and the piezoelectric layer; and
a second supporting layer, located between the first supporting layer and the piezoelectric layer;
wherein a thickness of the first supporting layer and a thickness of the second supporting layer are respectively greater than the thickness of the damage layer.

19. The electronic module as claimed in claim 18, wherein the thickness of the first supporting layer is less than 2λ; or
the thickness of the second supporting layer is less than 0.004λ.

20. The electronic module as claimed in claim 15, wherein the thickness of the damage layer is less than 3 nm; or
the thickness of the damage layer is less than or equal to 1 nm; or
a difference between a maximum and a minimum of the thickness of the piezoelectric layer is less than 40 nm; or
the distance between two adjacent interdigital transducers electrodes of the plurality of interdigital transducers electrodes is less than 1 μm.
